(19) United States
(12) Patent Application Publication
(10) Pub. No.: US 2024/0362374 A1
(43) Pub. Date: Oct. 31, 2024

(54) DYNAMIC CONTROL POINTS FOR INFRASTRUCTURE DESIGN AND SIMULATION

(71) Applicant: HYPERLOOP TECHNOLOGIES, INC., Dubai (AE)

(72) Inventors: Mohammed Ismaeel BABUR, Temple City, CA (US); Yury SOKOLOV, La Mesa, CA (US); Dihan YANG, Alhambra, CA (US)

(21) Appl. No.: 18/645,266

(22) Filed: Apr. 24, 2024

Related U.S. Application Data
(60) Provisional application No. 63/462,944, filed on Apr. 28, 2023.

(51) Int. Cl. G06F 30/20

(52) U.S. Cl. CPC G06F 30/20

(57) ABSTRACT

A method for generating a dynamic control point for generating an optimized curve includes determining, at a processor(s), an initial curve. A control point sampling interval and a condition are set by the processor(s). Multiple static control points are determined. The static control points are sampled based on the control point sampling interval. A sampled static control point is selected from the plurality of static control points based on the sampled static control point satisfying the condition. The sampled static control point is stored in a set of filtered control points. The set of filtered control points is sampled. A sampled filtered control point is selected based on the control point sampling interval. A dynamic control point is generated based on the sampled filtered control point.

### CROSS-REFERENCE TO RELATED APPLICATION

The present application claims the benefit of U.S. Provisional Patent Application No. 63/462,944, filed on Apr. 28, 2023, and titled “DYNAMIC CONTROL POINTS FOR INFRASTRUCTURE DESIGN AND SIMULATION,” the disclosure of which is expressly incorporated by reference in its entirety.

### BACKGROUND

Infrastructure is designed using software systems. In many cases, human users enter input in order to configure an alignment on terrain. For example, a civil engineer will design a corridor for power lines using a mouse and keyboard in a personal computer (“PC”) environment. Human-originated designs are often inefficient and, in some cases, dangerous to human lives. Therefore, having human-originated designs creates a risk, given that humans simply make mistakes when designing systems.

Optimizers are becoming an area of increasing focus in the design and simulation of infrastructure deployments—in part to reduce error created by humans. Further, optimizers are capable of addressing mathematically difficult problems that humans cannot. For example, a road may be placed within a mountain pass that has sections with varying grades. An optimizer may be configured to improve the configuration of the road.

One particular problem for optimizers is when progressive optimization is used. Control points are placed along a curve that is being optimized. However, the control points may deviate greatly from the optimization target. For example, control points that are constrained early in optimization may lead to suboptimal results. In other words, static control points may constrain a solution away from the optimized solution.

Therefore, it may be desirable to provide a solution that utilizes dynamic control points to improve optimization techniques associated with the design and simulation of infrastructure.

### SUMMARY

The present disclosure is set forth in the independent claims, respectively. Some aspects of the disclosure are described in the dependent claims.

In one aspect of the present disclosure, a method for generating a dynamic control point for generating an optimized curve includes determining, at at least one processor, an initial curve. The method also includes setting, at the at least one processor, a control point sampling interval and a condition. The method further includes determining, at the at least one processor, a number of static control points. The method still further includes sampling, at the at least one processor and based on the control point sampling interval, the number of static control points. The method also includes selecting, at the at least one processor, a sampled static control point from the number of static control points. The selection is based on the sampled static control point satisfying the condition. The method further includes storing, at the at least one processor, the sampled static control point in a number of filtered control points. The method still further includes sampling, at the at least one processor, the number of filtered control points. The method includes selecting, at the at least one processor, a sampled filtered control point, the selecting being based on the control point sampling interval. The method further includes generating, at the at least one processor and based on the sampled filtered control point, a dynamic control point.

Another aspect of the present disclosure is directed to an apparatus including means for determining, at at least one processor, an initial curve. The apparatus also includes means for setting, at the at least one processor, a control point sampling interval. The apparatus further includes means for setting, at the at least one processor, a condition. The apparatus further includes means for determining, at the at least one processor, a number of static control points. The apparatus further includes means for sampling, at the at least one processor and based on the control point sampling interval, the number of static control points. The apparatus further includes means for selecting, at the at least one processor, a sampled static control point from the number of static control points. The selection is based on the sampled static control point satisfying the condition. The apparatus further includes means for storing, at the at least one processor, the sampled static control point in a number of filtered control points. The apparatus further includes means for sampling, at the at least one processor, the number of filtered control points. The apparatus further includes means for selecting, at the at least one processor, a sampled filtered control point, the selecting being based on the control point sampling interval. The apparatus further includes means for generating, at the at least one processor and based on the sampled filtered control point, a dynamic control point.

In another aspect of the present disclosure, a non-transitory computer-readable medium with program code recorded thereon is disclosed. The program code is executed by at least one processor and includes program code to determine, at the at least one processor, an initial curve. The program code still further includes program code to set, at the at least one processor, a control point sampling interval. The program code also includes program code to set, at the at least one processor, a condition. The program code further includes program code to determine, at the at least one processor, a number of static control points. The program code still further includes program code to sample, at the at least one processor and based on the control point sampling interval, the number of static control points. The program code includes program code to select, at the at least one processor, a sampled static control point from the number of static control points. The selection is based on the sampled static control point satisfying the condition. The program code further includes program code to store, at the at least one processor, the sampled static control point in a number of filtered control points. The program code still further includes program code to sample, at the at least one processor, the number of filtered control points. The program code includes program code to select, at the at least one processor, a sampled filtered control point, the selecting being based on the control point sampling interval. The program code further includes program code to generate, at the at least one processor and based on the sampled filtered control point, a dynamic control point.

Another aspect of the present disclosure is directed to an apparatus having at least one memory and one or more processors coupled to the at least one memory. The processor(s) is configured to determine an initial curve. The processor(s) is still further configured to set a control point sampling interval. The processor(s) is also configured to set a condition. The processor(s) is further configured to determine a number of static control points. The processor(s) is also configured to sample, based on the control point sampling interval, the number of static control points. The processor(s) is configured to select a sampled static control point from the number of static control points. The selection is based on the sampled static control point satisfying the condition. The processor(s) is also configured to store the sampled static control point in a number of filtered control points. The processor(s) is further configured to sample the number of filtered control points. The processor(s) is still further configured to select a sampled filtered control point, the selecting being based on the control point sampling interval. The processor(s) is configured to generate, based on the sampled filtered control point, a dynamic control point.

### BRIEF DESCRIPTION OF DRAWINGS

The accompanying drawings, which are incorporated herein and constitute part of this specification, illustrate exemplary aspects of the claims, and together with the general description given above and the detailed description given below, serve to explain the features of the claims.

FIG. 1 is a block diagram illustrating a bounding region.

FIG. 2A is a block diagram illustrating a geographic information system (“GIS”) management system.

FIG. 2B is a block diagram illustrating a cost map data structure and a cost layer data structure.

FIG. 2C is a block diagram illustrating a dynamic control point module.

FIG. 2D is a block diagram illustrating a control point data structure.

FIG. 3A is a flowchart illustrating a process for operations associated with dynamic control points.

FIG. 3B is a flowchart illustrating a process for operations associated with dynamic control points.

FIG. 3C is a flowchart illustrating a process for operations associated with dynamic control points.

FIG. 4A is a view of a graph illustrating a relationship between distance and elevation.

FIG. 4B is a view of a graph illustrating a relationship between distance and elevation.

FIG. 4C is a view of a graph illustrating a relationship between distance and elevation.

FIG. 5 is a block diagram illustrating an example computing device suitable for use with the various aspects described.

FIG. 6 is a block diagram illustrating an example server suitable for use with the various aspects described.

### DETAILED DESCRIPTION

Various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the claims.

As stated above, progressive optimizers are being used more and more frequently in the design and simulation of infrastructure. For example, a human designer may configure an alignment and a profile of a corridor used by a power line system. The human designer may be generally adept at configuring the initial alignment and profile; however, the designer may not be particularly adept at optimizing the alignment and profile. While the initial design may potentially be viable, the results may be such that improvement is both achievable and desirable, hence the need for progressive optimization.

One particular challenge for progressive optimizers is constraining the next recursive level of optimization. For example, a profile may have an initial alignment that is roughly at the elevation of the ground. However, a progressive optimizer may, in certain situations, cause the optimized profile to greatly deviate from the ground elevation. A cause of the deviation is, in part, the use of static control points.

The disclosed solution is configured to generate and use dynamic control points in designing a curve for infrastructure. A curve may be an alignment and/or a profile. The dynamic control points enable the progressive optimizer to manage subsequent recursive levels within the optimization. Therefore, the progressive optimizer may be configured to generate improved curves, and in some aspects optimized curves, without deviating too greatly from the ground elevation (plus any adjustment for tunneling and bridging).

As shall be disclosed, the benefits of the disclosed solution may include, but are not limited to: decreasing time to market, increasing operating profit, decreasing power consumption, optimizing land use, increasing passenger and/or cargo throughput, protecting and/or preserving environmental resources, reducing pollution, reducing reliance on fossil fuels, preserving historical sites, preserving cultural sites, reducing capital costs of infrastructure, increasing passenger safety, preserving biological resources, reducing noise, and/or increasing reliability and maintainability of infrastructure, for example.

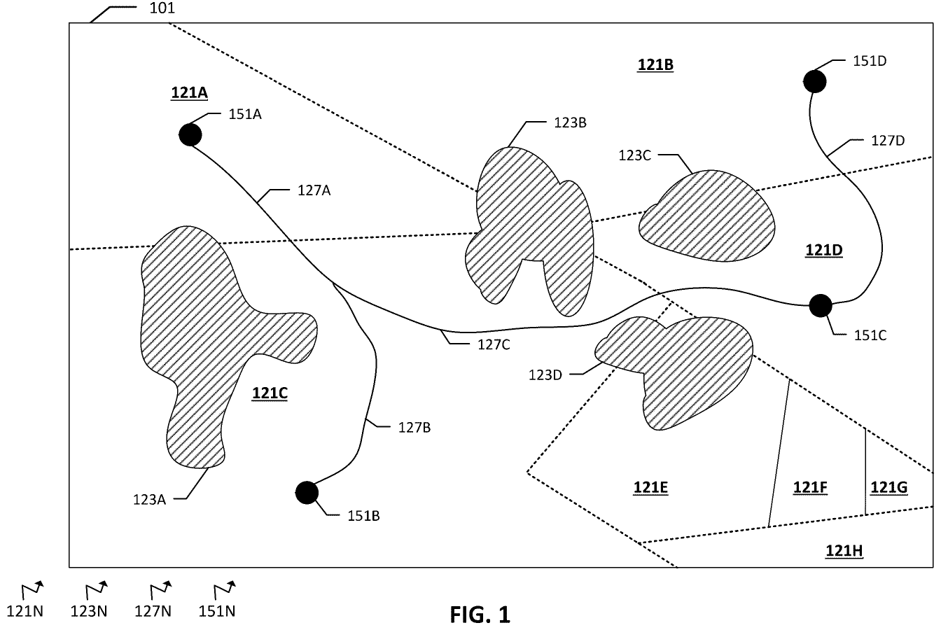

FIG. 1 is a block diagram illustrating a bounding region 101. The bounding region 101 comprises a plurality of parcels 121N, a plurality of obstructions 123N, and a plurality of alignment curves 127N. In general, the bounding region 101 is associated with a real-world location. The bounding region 101 may be any conceivable shape—and is shown in the instant view as a simple rectangle. The disclosed solution is configured to optimize an alignment (or profile) of a corridor within the bounding region 101.

A corridor may be considered an area of land upon which infrastructure may be built. For instance, a corridor may support a road, a freeway, a tunnel, a railway, a hyperloop route, a high-speed rail route, an airport, power lines, gas lines, sewer lines, coastal walls, bridges, sea walls, or a combination thereof. The disclosed solution is configured to improve, and in some aspects, optimize an alignment curve that is associated with the corridor found in the bounding region 101.

The plurality of alignment curves 127N comprises a first alignment curve 127A, a second alignment curve 127B, a third alignment curve 127C, and a fourth alignment curve 127D. The plurality of alignment curves 127A may be comprised of optimized alignment curves and/or initial alignment curves. An initial alignment curve may be an alignment curve that has been created by a user or a process, for instance. In either case, the initial alignment curve is generally not optimized. On the other hand, an optimized alignment curve is optimized, as the name suggests. For example, the alignment curve 127A may be in an optimized state whereas the alignment curve 127B is not optimized. The alignment curve 127A may be in the optimized state based on minimizing a cost function associated with the alignment curve 127A.

The plurality of parcels 121N comprises a first parcel 121A, a second parcel 121B, a third parcel 121C, a fourth parcel 121D, a fifth parcel 121E, a sixth parcel 121F, a seventh parcel 121G, and an eighth parcel 121H. The plurality of parcels 121N comprises varying cost values and thus impose different costs on the plurality of alignment curves 127N. For example, the third parcel 121C may be a marsh associated with high traversal costs when constructing roads.

The bounding region 101 comprises a plurality of obstructions 123N. The plurality of obstructions 123N comprises a first obstruction 123A, a second obstruction 123B, a third obstruction 123C, and a fourth obstruction 123D. The plurality of obstructions 123N may be anything that causes costs to be so high that traversal is simply not feasible. The disclosed solution is configured to account for the plurality of obstructions 123N when developing an optimized configuration of the plurality of alignment curves 127N. For instance, the best-suited solver(s) may be selected to address the plurality of obstructions 123N in the bounding region 101.

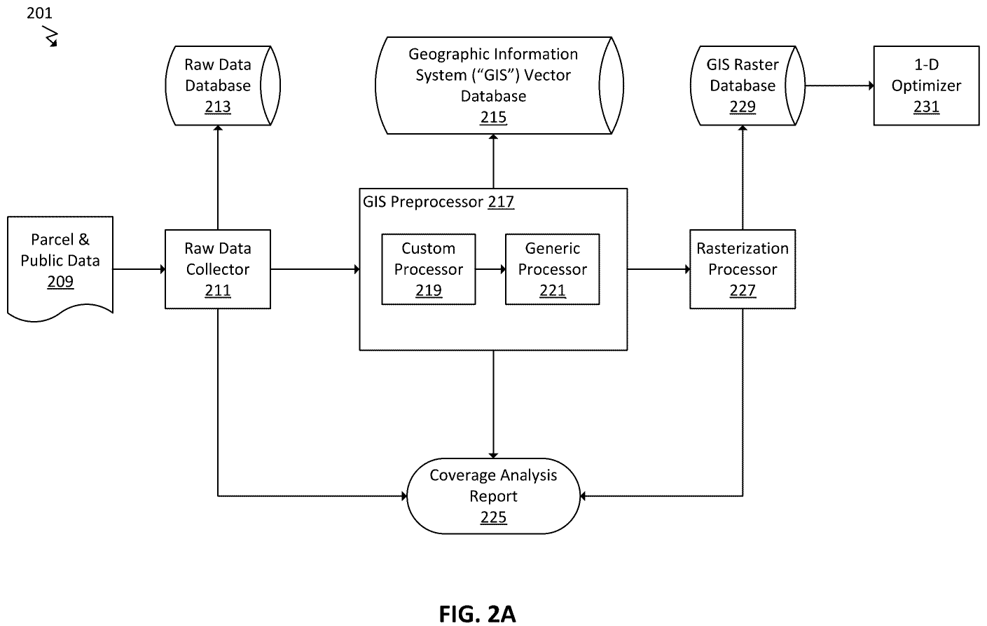

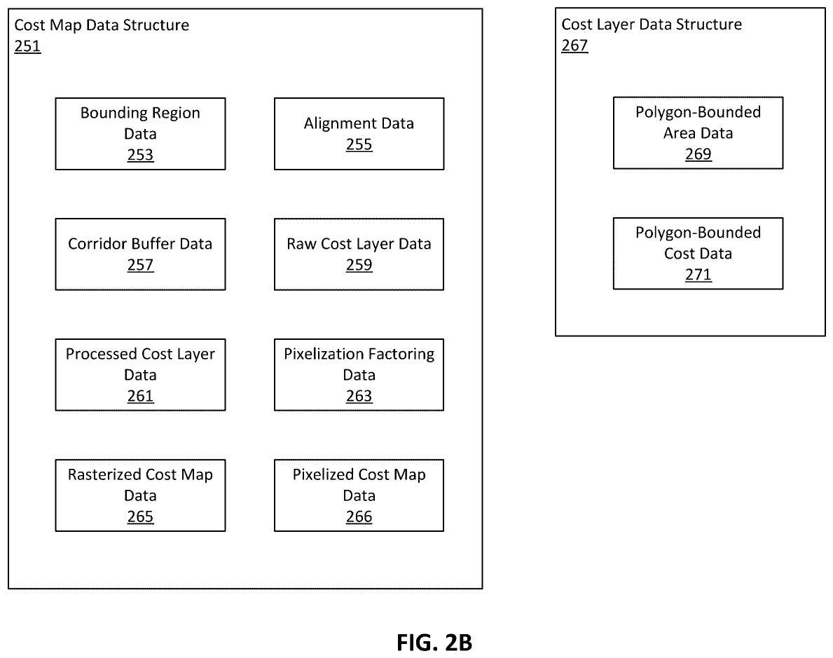

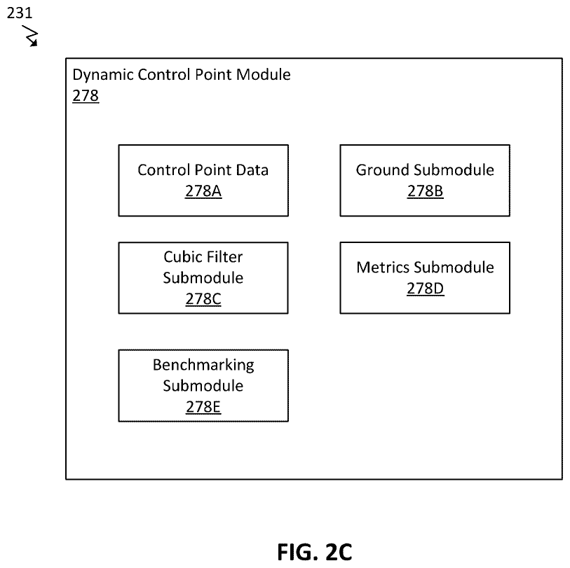

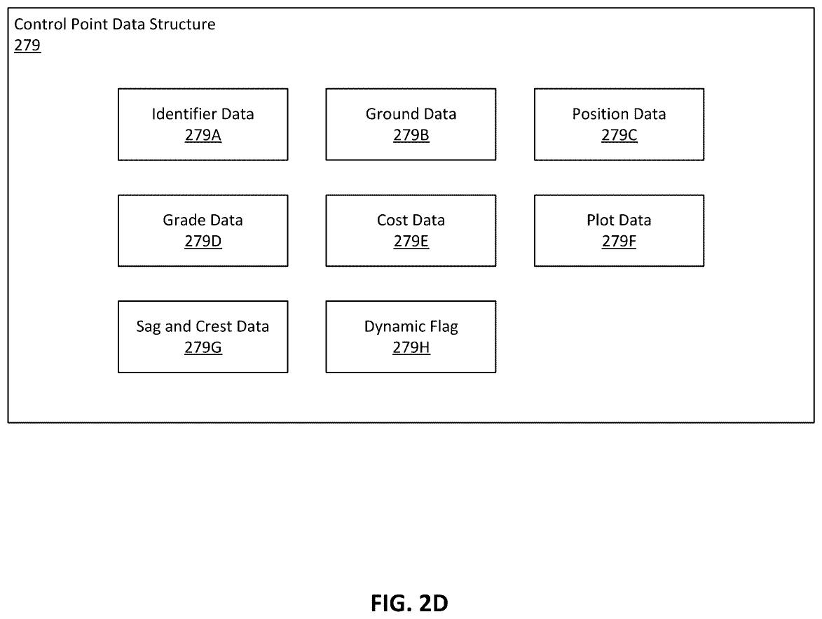

FIG. 2A is a block diagram illustrating a geographic information system (“GIS”) management system 201. The GIS management system 201 may be configured to provide GIS information to a one-dimensional (“1-D”) optimizer 231. A coverage analysis report 225 may also be generated by the GIS management system 201 for use by designers, civil engineers, operators, etc.

The 1-D optimizer 231 may be configured to optimize for a single parameter (e.g., one dimension) along a particular alignment. In general, the 1-D optimizer 231 may create an optimal design in one dimension, in which that one dimension includes multiple design and configuration parameters. For example, the 1-D optimizer 231 may optimize a vertical profile of an alignment to reduce capital expenditure costs that are necessary to deploy a linear infrastructure route (e.g., the route 115A). The 1-D optimizer 231 also accounts for vehicle acceleration limits, passenger acceleration limits, jerk limits, grade constraints (e.g., gradeability), motor acceleration, motor power capabilities, braking capabilities, thermal limits, etc. The 1-D optimizer 231 may also consider parameters from other dimensions to understand some three-dimensional constraints.

The 1-D optimizer 231 may rely on local multivariate optimization for a piecewise continuous spline with non-linear constraints using a Broyden-Fletch-Goldfarb-Shanno (“BFGS”) algorithm and/or a Sequential Least Squares Programming (“SLSQP”) algorithm. Optimization types for entities with multi-order continuity at the boundaries may include a genetic algorithm and/or a particle swarm algorithm. Depending on the context, one of skill in the art will appreciate that one or both algorithms may be utilized.

The 1-D optimizer 231 is further configured to be utilized during trip simulations such that kinematic-related optimizations may be tested. For example, peak velocity may be selected as the trajectory (or drive strategy) to optimize; the trip simulation may then utilize and validate the 1-D optimization of kinematics related to a hyperloop vehicle during operation. Likewise, the trip simulation may inform the 1-D optimizer 231 of any deficiencies discovered during the simulation, and/or be used to understand the full kinematic constraints to be considered for the 1-D optimizer 231 to further optimize an alignment and profile.

The GIS management system 201 is configured to receive parcel and public data 209. The parcel and public data 209 may be parcel maps of land areas. In one aspect, the parcel maps may be augmented with prices indicating the value of the land (as well as any improvements). The value of land may be considered by the 1-D optimizer 231 when optimizing an alignment and profile. In one aspect, the parcel and public data 209 may be any public data relating to land value, land use, land prices, property taxes, ownership, encumbrances, historical status, environmental protection status, topography, utilities, geology, water bodies, vegetation, or maps based on certain analyses including flood maps, seismic risk maps, or the like. Such information may be utilized by the 1-D optimizer 231 in order to generate optimized alignments and potentially profiles.

A raw data collector 211 may be configured to configure and store data of various types and formats. One of skill in the art will appreciate that GIS data may be received in many different formats. For example, GIS data may be received as vectorized data or rasterized data. The raw data collector 211 processes disparate types of data. One of skill in the art will appreciate that such a benefit provides users with ease of use because various types of data may be aggregated and processed such that the user is free to focus on designing the route.

A raw data database 213 may be accessible by the raw data collector 211 in order to write or read raw GIS data. The raw data collector 211 is configured to output the raw GIS data to the coverage analysis report 225 such that a consumer of the coverage analysis report 225 may access the raw GIS data supporting other processed outputs (e.g., rasterizations). The coverage analysis report 225 contains the details of what factors and objectives were considered when determining an alignment and profile. For example, a hyperloop route may be optimized such that the hyperloop route traverses a plot of land. During eminent domain proceedings, the coverage analysis report 225 provides a detailed and objective source of information to support or refute an eminent domain claim.

The coverage analysis report 225 may be regenerated based on considerations uncovered as part of new events. For example, the coverage analysis report 225 may be regenerated during an eminent domain proceeding in order to arrive at a more optimized solution for stakeholders involved in the eminent domain proceedings. One of skill in the art will appreciate that the disclosed solution may arrive at the same optimization in many cases; nevertheless, the coverage analysis report 225 provides a critical source of information as to what data was considered when arriving at the same optimization.

A GIS preprocessor 217 comprises a custom processor 219 and a generic processor 221. The GIS preprocessor 217 may be configured to preprocess the raw GIS data sent by the raw data collector 211. The raw GIS data may thereafter be considered preprocessed GIS data. The preprocessed GIS data may be written to the coverage analysis report 225 or to a GIS vector database 215. The GIS vector database 215 is accessible by the GIS preprocessor 217 in order to write or read the vectorized data.

The custom processor 219 may be configured to address situations where the cost of traversing a particular GIS data layer is unknown (or unsatisfactory for optimization). The GIS data layer may be manipulated such that a cost function may be derived for an optimization. For example, a GIS data layer for terrain may only include raw elevation data; the custom processor 219 may use the raw elevation data to generate a meaningful cost metric, such as a slope raster in order to have a slope cost function. As another example, a body of water represented in a GIS data layer may not have a cost function associated with crossing the body of water. Likewise, the custom processor 219 generates a cost function based on traversing the body of water via a tunnel or bridge. The output of the custom processor 219 is then communicated to the generic processor 221 for further operations (e.g., normalization).

The generic processor 221 may be configured to normalize any cost functions in the GIS data layer. Often, the GIS data layer contains the necessary cost functions. For example, a terrain map may have associated therewith the prices of land. However, even with a cost function present, the GIS data layer may still need further normalization and processing prior to consumption by additional artificial intelligence (“AI”) algorithms, systems, modules, etc.

A rasterization processor 227 may be configured to receive the preprocessed GIS data from the GIS preprocessor 217. The rasterization processor 227 is configured to rasterize any data into an aggregated image with multiple raster bands. For example, the GIS data received from the GIS preprocessor 217 may be vectorized data. As such, the rasterization processor 227 may rasterize the vectorized data into a single image with multiple raster bands. Each raster band may be further placed in a data structure, such as a tree or other structure, based on the various resolutions of the raster bands (or the entire image itself), thus providing a user with the capability to explore the data in an efficient and responsive manner. The rasterization processor 227 is configured to output the rasterized GIS data to a GIS raster database 229. In one aspect, the GIS raster database 229 then communicates the rasterized GIS data to the 1-D optimizer 231.

FIG. 2B is a block diagram illustrating a cost map data structure 251 and a cost layer data structure 267. The cost map data structure 251 comprises bounding region data 253, alignment data 255, corridor buffer data 257, raw cost layer data 259, processed cost layer data 261, pixelization factoring data 263, rasterized cost map data 265, and pixelized cost map data 266. The cost layer data structure 267 comprises polygon-bounded area data 269 and polygon-bounded cost data 271.

The cost map data structure 251 may be configured to encapsulate data relating to the two-dimensional (“2-D”) cost maps as well as metadata related thereto. The bounding region data 253 may be configured to define a 2-D array that represents the search space as well as the physical space beyond the search space. For example, a bounding region may be defined as an entire municipality in which an alignment is to be deployed. In one aspect, the 2-D grid is defined by latitude and longitude coordinates forming a bounding box.

The alignment data 255 may be configured to represent one or more curves forming the alignment of a corridor. In one aspect, the alignment data 255 corresponds to the plurality of alignment curves 127N, shown in FIG. 1 above. The alignment data 255 is further configured to store additional metadata. For example, the alignment data 255 may comprise data that mathematically relates the alignment curves to one another.

In one aspect, the alignment data 255 may be initialized with an initial alignment in order to start subsequent operations relating to search space optimization. For example, initial alignment data may include a simple alignment within the bounding region. The simple alignment may be utilized to generate a corridor buffer that comprises the extents of the actual search space of the 1-D optimizer 231.

One of skill in the art will appreciate that the alignment is distinct from the profile. For the purposes of the disclosed solution, the alignment is of interest because the alignment generally defines where the profile will be deployed. In other words, the profile may be configured to be overlaid on the ultimate alignment placement. Thus, the alignment data 255 may be updated and augmented to include additional data relating the alignment data 255 to any profile data (not shown). In one aspect, the alignment data 255 is augmented by the 1-D optimizer 231 such that profile data may readily be associated with the alignment data 255.

The corridor buffer data 257 may be configured to define a corridor at or near the initial alignment, as stored in the alignment data 255. As stated, the alignment data 255 may comprise initial alignment data within the bounding region data 253. The bounding region data 253 may relate to the larger extent of the search space, and the corridor buffer data 257 is the more relevant area of the search space. As such, the 1-D optimizer 231 is more efficient when determining optimized alignments (and even profiles). Thus, the initial alignment data forms the basis for corridor buffer data 257.

The raw cost layer data 259 may be configured to store one or more layers containing cost-related data. For example, a parcel map may be included in a layer of the raw cost layer data 259 in order to demarcate the boundaries of various land parcels. Further, a land value map may be included as yet another layer of the raw cost layer data 259. As such, the cost map data structure 251 contains data sufficient to generate processed cost layer data 261, which may be configured to provide the 1-D optimizer 231 the data for alignment optimization.

The processed cost layer data 261 may be configured to store the raw cost layer data 259 after having been processed by the GIS management system 201 (and related processes). As stated, the 1-D optimizer 231 is configured to perform advanced search and artificial intelligence (AI) techniques on the processed cost layer data 261 in order to improve or even optimize the alignment data 255 further.

The pixelization factoring data 263 may be configured to store data relating to pixelization techniques used to fill in gaps in the raw cost layer data 259 and/or the processed cost layer data 261. Thus, the pixelization factoring data 263 is such that pixelization operations may be controlled, managed, observed, optimized, etc.

The rasterized cost map data 265 may be configured to provide a 2-D array of data that represents the processed cost layer data 261. The rasterized cost map data 265 may be represented as a bitmap, in one aspect. Having the data represented in such a 2-D array provides consolidated data that the 1-D optimizer 231 may utilize to improve or even optimize the alignment data 255.

The pixelized cost map data 266 may be configured to provide a 2-D array of data that represents the processed cost layer data 261. One of skill in the art will appreciate that the rasterized cost map data 265 may have data gaps. In contrast, the pixelized cost map data 266 is configured to address any data gaps in the 2-D array of the rasterized cost map data 265.

The cost layer data structure 267 may be configured to store data relating to real-world locations. The boundaries of the real-world locations may be stored as polygons in the cost layer data structure 267. In one aspect, the raw cost layer data 259 and the processed cost layer data 261 utilize several cost layer data structures 267 in order to generate an optimized search space for consumption by the 1-D optimizer 231. The cost layer data structure 267 instances may be represented in the resulting rasterized cost map data 265.

The polygon-bounded area data 269 may be configured to store coordinates, lines, vectors, rays, etc., any of which form a polygon-bounded region related to the real-world deployment of an alignment. For example, a polygon-bounded area may be a parcel of land that is available for purchase. As another example, a polygon-bounded area may be a nature preserve that is not available for deployment of infrastructure.

The polygon-bounded cost data 271 generally contains data relating to the cost of the polygon-bounded area within the polygon-bounded area data 269. As stated, cost is not simply monetary values required to traverse the polygon-bounded area with an alignment. Cost may include other resources associated with an alignment to traverse a polygon-bounded area. For example, the cost may include the number of liters of water required to pour concrete within the polygon-bounded area.

FIG. 2C is a block diagram illustrating a dynamic control point module 278. The dynamic control point module 278 may be configured to generate dynamic control points. Use of dynamic control points avoids situations where a progressive optimizer (e.g., the 1-D optimizer 231) is constrained away from a more-optimized solution. In other words, the dynamic control points enable the 1-D optimizer 231 to generate improved solutions while still maintaining the progressive optimization approach. The dynamic control point module 278 comprises control point data 278A, a ground submodule 278B, a cubic filter submodule 278C, a metrics submodule 278D, and a benchmarking submodule 278E.

The control point data 278A may be configured to manage both static control points and dynamic control points. For purposes of clarity, both static and dynamic control points are control points within a given curve (e.g., for a profile). Static control points are placed at fixed intervals along a given curve (e.g., the alignment curve 127C from FIG. 1 above). For example, a static control point may be placed every 500 meters along a corridor for natural gas lines.

Dynamic control points are configured to be placed at various positions along a curve. A static control point has a drawback of potentially leading progressive optimization away from goals of the 1-D optimizer 231. For instance, a static control point may unduly (or non-optimally) constrain a curve such that optimization may not be fully realized. However, dynamic control points enable progressive optimization techniques to not unduly be constrained during subsequent optimizations (e.g., recursive operations by the 1-D optimizer 231). Further, the progressive optimization will not result in being constrained away from more-optimized solutions.

The control point data 278A comprises various collections of control points. For example, processes may store intermediate results related to control points in the control point data 278A, often for the purpose of generating dynamic control points. The ground submodule 278B may include data relating to the terrain associated with a curve. For example, GIS data may be utilized by the ground submodule 278B. Above-grade and below-grade adjustment data may be stored in the ground submodule 278B.

The cubic filter submodule 278C may be configured to provide cubic filtering. That is, the cubic filter submodule 278C may ensure that constraints to the second derivative may be satisfied. The metrics submodule 278D may be configured to generate metrics and analytics for users based on the benchmark test. For example, a benchmark test may be generated by the benchmarking submodule 278E; the metrics submodule 278D may present the results of the benchmark test in terms easily understood by human users. For instance, the metrics submodule 278D may present the maximum positive grade of a profile curve.

The benchmarking submodule 278E may be configured to perform benchmarking tests against a curve. For example, the alignment curve 127A may be subject to many variants of progressive optimization. As such, the variants may require testing in order to be evaluated against one another. In one aspect, such evaluation is performed by AI.

FIG. 2D is a block diagram illustrating a control point data structure 279. The control point data structure 279 may be configured to utilize data associated with both static and dynamic control points. In one aspect, the dynamic control point module 278 is configured to manage a plurality of control point data structures as control point data 278A. The control point data structure 279 comprises identifier data 279A, ground data 279B, position data 279C, grade data 279D, cost data 279E, plot data 279F, sag and crest data 279G, and a dynamic flag 279H.

The identifier data 279A may be configured to uniquely identify each control point. In one aspect, the identifier data 279A is used by the control point data 278A to perform operations (e.g., sampling). The ground data 279B may be configured to store information related to terrain that is associated with the position data 279C. The ground data 279B may comprise information related to adjustments based on bridging and/or tunneling.

The position data 279C may be configured to store the position of a control point in the optimization. For example, a profile may be associated with elevation and distance along a given alignment. The position data 279C in such a case would be the elevation and distance. One feature of dynamic control points is the capability to move the dynamic control points along an axis to avoid constraining optimizations at non-optimal solutions.

The grade data 279D may be configured to store information related to the grade associated with the position data 279C. The cost data 279E may be configured to associate the control point data structure 279 with a cost to traverse the cost map data (e.g., as stored in the cost map data structure 251). The plot data 279F may be configured to represent the control point with a multidimensional graph. The sag and crest data 279G may be configured to store any deviation from ground level. The dynamic flag 279H may be configured to identify whether the control point is static or dynamic.

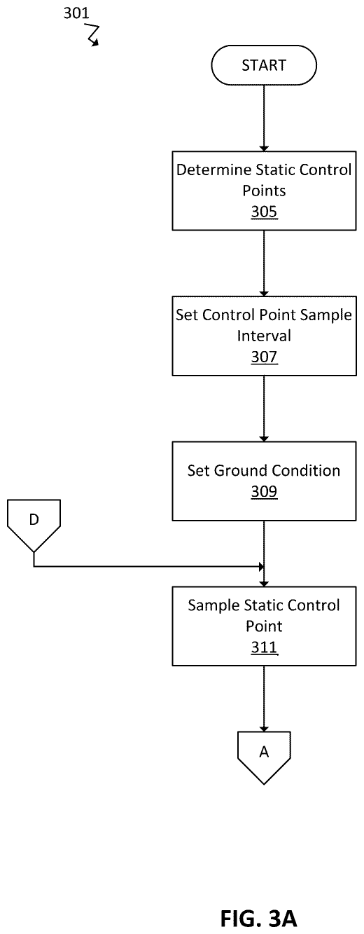

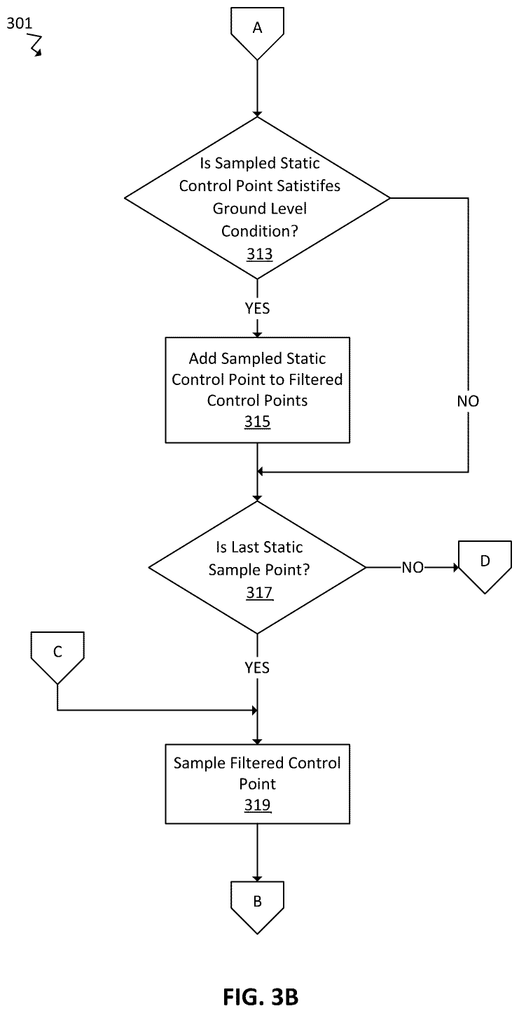

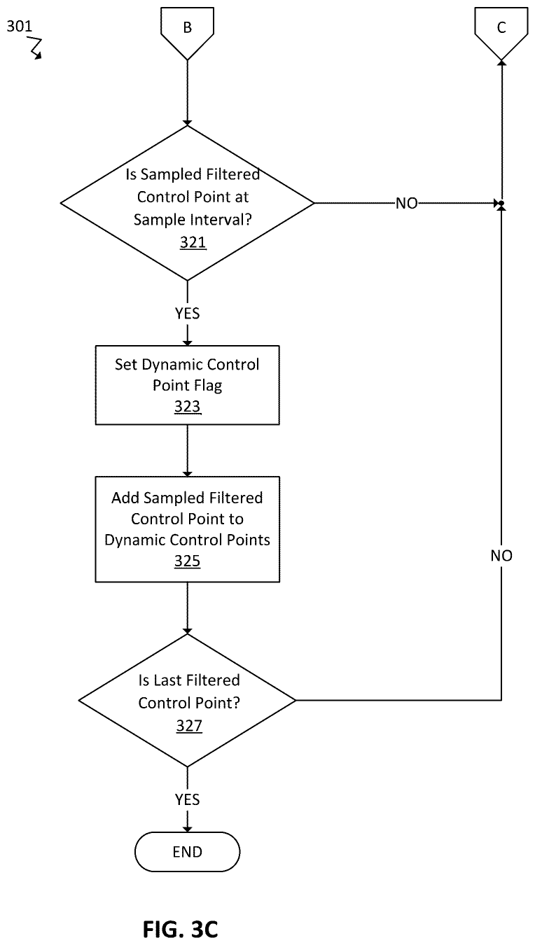

FIG. 3A is a flowchart illustrating a process 301 for operations associated with dynamic control points. The process 301 may be configured to generate dynamic control points. In one aspect, the process 301 is part of a larger optimization process performed by the 1-D optimizer 231. The process 301 begins at the start block and proceeds to block 305.

At the block 305, the process 301 determines static control points for a curve. The curve may be associated with terrain between two waypoints. The curve may, for example, lie in a plane that is perpendicular to the ground or parallel to the ground. For example, in the case of alignment, the curve may be parallel to the ground (or horizon). For example, in the case of profile, the curve may be perpendicular to the ground. However, these examples are merely for case of explanation and not limiting. The process 301 then proceeds to block 307.

At the block 307, the process 301 sets a control point sample interval. The control point sample interval may be based on distance along a curve. For example, the corridor length may have an interval of 1,000 meters between the waypoints 151A, 151B, thus yielding ten intervals within a 10-kilometer corridor length. The process 301 then proceeds to block 309.

At the block 309, the process 301 sets a ground condition. The determination of whether a control point is static or dynamic may be based on whether the control point meets a ground condition. The ground condition may be the point at which the profile reaches the ground level. For example, a profile may allow for some amount of tunnelling through mountains. As such, the ground condition is below grade due to the allowance of tunnelling. Conversely, the ground condition may be above grade, such as that enabled by bridging. The process 301 then proceeds to block 311.

At the block 311, the process 301 samples a static control point. In one aspect, the static control point is stored within the control point data 278A. At initialization of the alignment or profile, the static control points are distributed throughout the curve. The initial static control points are then sampled to generate filtered control points. The filtered control points act as a source to determine what, if any, control points should be made dynamic. Therefore, the process 301 samples each static control point to determine whether the sampled static control point is a candidate for the filtered control points. The process 301 then proceeds to off-page reference A which continues at FIG. 3B.

FIG. 3B is a flowchart illustrating the process 301 for operations associated with dynamic control points. The process 301 continues from off-page reference A and proceeds to decision block 313. At the decision block 313, the process 301 determines whether the sampled control point satisfies the ground condition. The ground condition may be satisfied by crossing a boundary formed by the ground-level, as adjusted by any tolerance value. For example, a ground condition may be the ground-level elevation minus 25 meters to allow for below-grade tunnelling. If the process 301 determines the sample control point does not satisfy the ground level condition, the process 301 proceeds along the NO branch to decision block 317. If the process 301 determines the sample control point satisfies the ground level condition, the process 301 proceeds along the YES branch to block 315.

The example of a ground condition is given for the decision block 313 because the number of possible conditions is beyond the scope of this disclosure. For instance, an alignment curve may have a condition related to ground stability in order to optimize toward placing infrastructure in the most stable ground possible. Thus, the alignment curve may have a ground stability condition.

At the block 315, the process 301 adds the sampled static control point to the filtered control points. As stated, the filtered control points are control points that have satisfied the ground condition. One aim of the process 301 is to ensure that subsequent optimizations are not constrained too far from the ground condition. The process 301 then proceeds to decision block 317.

At the decision block 317, the process 301 determines whether the sampled static control point is the last point in the plurality of control points. If the process 301 determines that the sampled static control point is not the last static control point in the plurality of static control points, the process 301 proceeds along the NO branch to the off-page reference D which continues at FIG. 3A. One of skill in the art will appreciate that the off-page reference D returns to the block 311 in order to continue sampling static control points to determine which static control points may be marked as dynamic control points. As part of that determination, filtered control points will be identified by the iterations of the process 301.

Returning to the decision block 317, if the process 301 determines that the sampled static control point is the last static control point in the plurality of control points, then the process 301 proceeds along the YES branch to block 319. The process 301 is prepared to sample the filtered control points in order to generate one or more dynamic control points.

At the block 319, the process 301 samples the plurality of filtered control points for a sample filtered control point. The sampled filtered control point is a candidate to become a dynamic control point. The quantity of dynamic control points may be less than that of the filtered control points. The process 301 then proceeds to off-page reference B which continues at FIG. 3C.

FIG. 3C is a flowchart illustrating the process 301 for operations associated with dynamic control points. The process 301 continues at the off-page reference B and proceeds to decision block 321.

At the decision block 321, the process 301 determines whether the sampled filtered control point is at the sample interval. If the process 301 determines that the sampled filtered control point is not at the sample interval, the process 301 proceeds along the NO branch to the off-page reference C. The off-page reference C continues at FIG. 3B and proceeds to block 319.

If the process 301 determines that the sampled filtered control point is at the sample interval, the process 301 proceeds along the YES branch to block 323. At the block 323, the process 301 sets the dynamic flag 279H for the sampled filtered control point. The dynamic flag 279H provides an indicator to subsequent optimization operations of the 1-D optimizer 231 for the purposes of progressive optimization. In one aspect, the dynamic flag 279H is simply the generation of a dynamic control point based on the sampled filtered control point. The process 301 then proceeds to block 325.

At the block 325, the process 301 adds the sampled filtered control point to the plurality of dynamic control points. The plurality of dynamic control points may be associated with the control point data 278A. The process 301 then proceeds to decision block 327.

At the decision block 327, the process 301 determines whether the sampled filtered control point is the last filtered control point in the plurality of filtered control points. In one aspect, if the filtered control point is within the sample interval, the process 301 simply adds the filtered control point to the plurality of dynamic control points because the process 301 is reaching the end of the curve.

If the process 301 determines that the sampled filtered control point is not the last filtered control point in the plurality of filtered control points, the process 301 proceeds along the NO branch to the off-page reference C. Similar to the decision block 321, the process 301 is searching for candidate dynamic control points in the plurality of filtered control points. If the process 301 determines that the sampled filtered control point is the last filtered control point in the plurality of filtered control points, the process 301 proceeds along the YES branch to the end block and terminates.

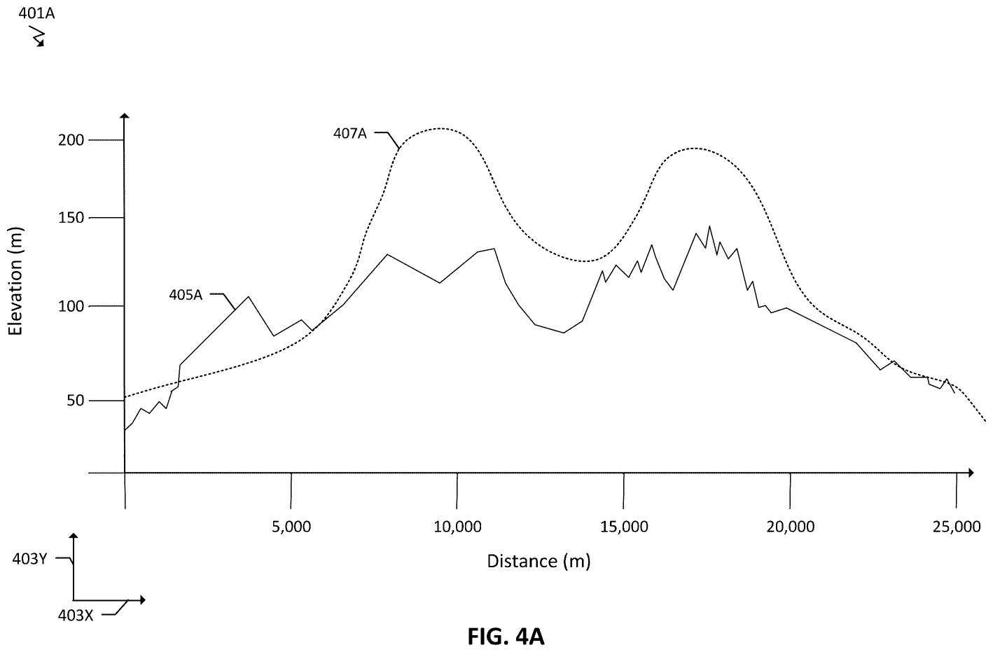

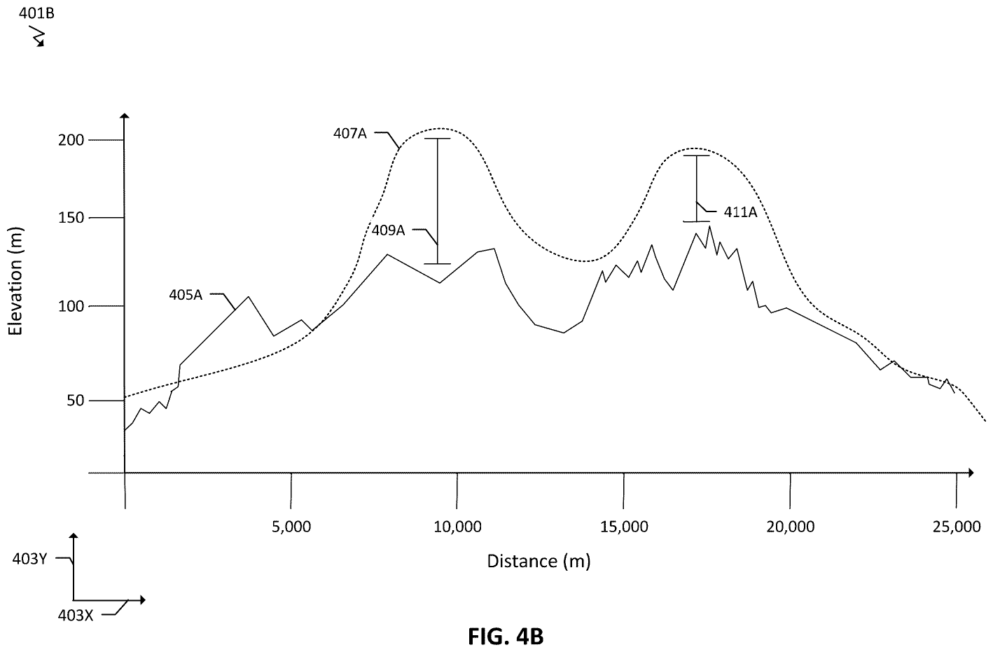

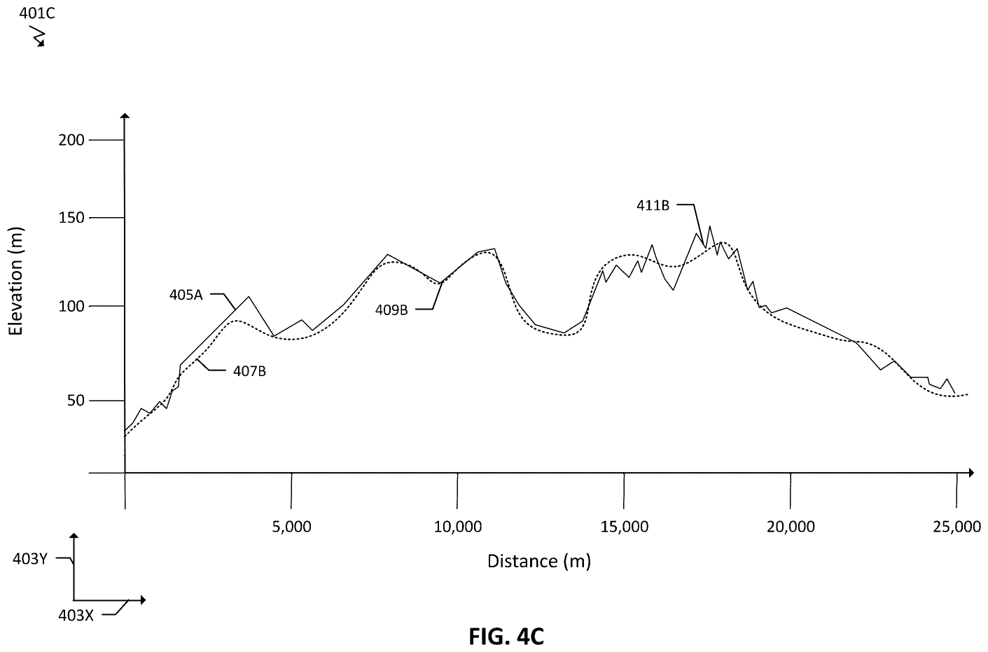

FIG. 4A is a view 401A of a graph illustrating a relationship between distance and elevation. An x-axis 403X and a y-axis 403Y are shown for reference throughout FIG. 4A through FIG. 4C. A terrain line 405A generally depicts the elevation of a given point of terrain along the axis 403X. As shown, the terrain line 405A corresponds to a rising mountain with two prominent peaks.

A non-dynamic profile line 407A generally depicts an initial or suboptimal state of a profile associated with an alignment. The non-dynamic profile line 407A comprises only static control points. The static control points may, for example, be fixed to the terrain line elevation at a constant sampling spacing or may be fixed at an elevation relative to the ground at a constant sampling spacing. The non-dynamic profile line 407A may have a fairly large deviation from the terrain line 405A. Therefore, the view 405A has not used the operations of the process 301 in order to generate dynamic control points. One of skill in the art will appreciate that the non-dynamic profile line 407A may have been optimized without the use of dynamic control points—yet the non-dynamic profile line 407A is technically optimized in the strict sense.

As an example, the alignment curve 127D corresponds to the non-dynamic profile line 407A. Further, the waypoints 151C, 151D form the origin and terminal for the distance shown in the view 401A. As such, the waypoints 151C, 151D are roughly 25,000 meters apart.

FIG. 4B is a view 401B of a graph illustrating a relationship between distance and elevation. The view 401B adds two reference distances, a distance 409A and a distance 411A. The distances 409A, 411A show the deviation of the non-dynamic profile line 407A from the terrain line 405A.

FIG. 4C is a view 401C of a graph illustrating a relationship between distance and elevation. The view 401C illustrates an optimized profile line 407B. As disclosed at FIG. 4B above, the non-dynamic profile line 407A uses only static control points—as such, the non-dynamic profile line 407A has deviations measured by the distances 409A, 411A. However, via use of the process 301, a first distance 409B and a second distance 411B are much closer to the terrain line 405A. In other words, the view 401C shows how the process 301 avoids unduly constraining the optimized profile line 407B away from the terrain line 405A.

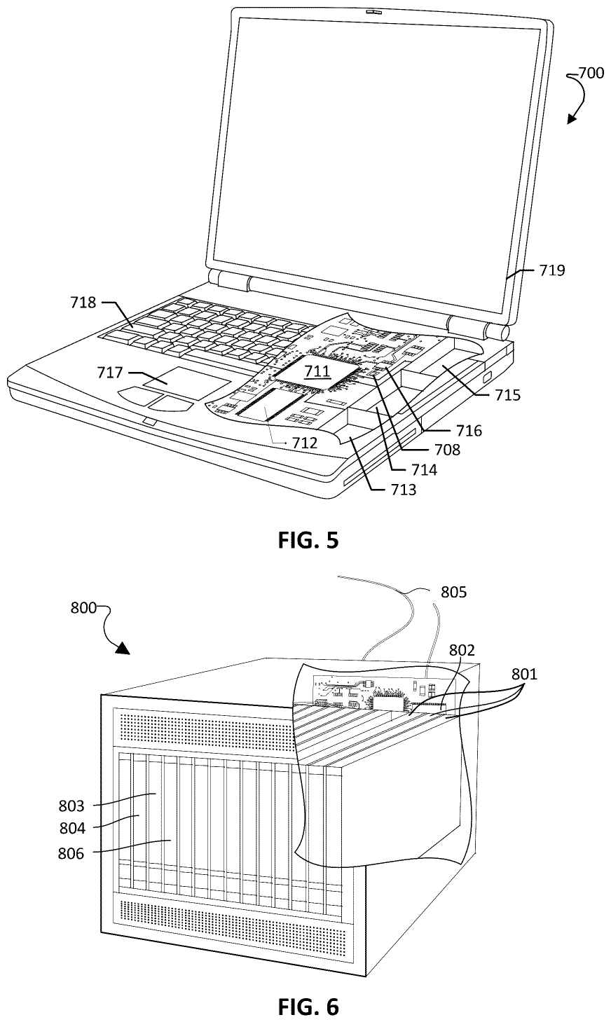

FIG. 5 is a block diagram illustrating a computing device 700 suitable for use with the various described aspects. The computing device 700 is configured to store and execute the GIS management system 201, the cost map data structure 251, the cost layer data structure 267, the dynamic control point module 278, the control point data structure 279, the process 301, and the views 401A, 401B, 401C.

The computing device 700 may include a processor 711 (e.g., an ARM processor) coupled to volatile memory 712 (e.g., DRAM) and a large capacity nonvolatile memory 713 (e.g., a flash device). Additionally, the computing device 700 may have one or more antenna 708 for sending and receiving electromagnetic radiation that may be connected to a wireless data link and/or cellular telephone transceiver 716 coupled to the processor 711. The computing device 700 may also include an optical drive 714 and/or a removable disk drive 715 (e.g., removable flash memory) coupled to the processor 711.

The computing device 700 may include a touchpad touch surface 717 that serves as the computing device's 700 pointing device, and thus may receive drag, scroll, flick etc., gestures similar to those implemented on computing devices equipped with a touch screen display as described above. In one aspect, the touchpad touch surface 717 may be integrated into one of the computing device's 700 components (e.g., a display 719). In one aspect, the computing device 700 may include a keyboard 718 which is operable to accept user input via one or more keys within the keyboard 718. In one configuration, the computing device's 700 housing includes the touchpad touch surface 717, the keyboard 718, and the display 719 all coupled to the processor 711. Other configurations of the computing device 700 may include a computer mouse coupled to the processor (e.g., via a USB input) as are well known, which may also be used in conjunction with the various aspects described.

FIG. 6 is a block diagram illustrating a server 800 suitable for use with the various described aspects. The server 800 is configured to store and execute the GIS management system 201, the cost map data structure 251, the cost layer data structure 267, the dynamic control point module 278, the control point data structure 279, the process 301, and the views 401A, 401B, 401C.

The server 800 may include one or more processor assemblies 801 (e.g., an x86 processor) coupled to volatile memory 802 (e.g., DRAM) and a large capacity nonvolatile memory 804 (e.g., a magnetic disk drive, a flash disk drive, etc.). As illustrated in instant figure, processor assemblies 801 may be added to the server 800 by insertion into the racks of the assembly. The server 800 may also include an optical drive 806 coupled to the processor assemblies 801. The server 800 may also include a network access interface 803 (e.g., an ethernet card, WIFI card, etc.) coupled to the processor assemblies 801 for establishing network interface connections with a network 805. The network 805 may be a local area network, the Internet, the public switched telephone network, and/or a cellular data network (e.g., LTE, 5G, etc.).

The foregoing method descriptions and diagrams/figures are provided merely as illustrative examples and are not intended to require or imply that the operations of various aspects must be performed in the order presented. As will be appreciated by one of skill in the art, the order of operations in the aspects described may be performed in any order. Words such as “thereafter,” “then,” “next,” etc. are not intended to limit the order of the operations; such words are used to guide the reader through the description of the methods and systems described. Further, any reference to claim elements in the singular, for example, using the articles “a,” “an,” or “the” is not to be construed as limiting the element to the singular.

Various illustrative logical blocks, modules, components, circuits, and algorithm operations described in connection with the aspects described may be implemented as electronic hardware, computer software, or combinations of both. To clearly illustrate this interchangeability of hardware and software, various illustrative components, blocks, modules, circuits, operations, etc. have been described generally in terms of their functionality. Whether such functionality is implemented as hardware or software depends upon the particular application and design constraints imposed on the overall system. One of skill in the art may implement the described functionality in varying ways for each particular application, but such implementation decisions should not be interpreted as causing a departure from the scope of the claims.

The hardware used to implement various illustrative logics, logical blocks, modules, components, circuits, etc. described in connection with the aspects described may be implemented or performed with a general purpose processor, a digital signal processor (“DSP”), an application specific integrated circuit (“ASIC”), a field programmable gate array (“FPGA”) or other programmable logic device, discrete gate logic, transistor logic, discrete hardware components, or any combination thereof designed to perform the functions described. A general-purpose processor may be a microprocessor, a controller, a microcontroller, a state machine, etc. A processor may also be implemented as a combination of receiver smart objects, e.g., a combination of a DSP and a microprocessor, a plurality of microprocessors, one or more microprocessors in conjunction with a DSP core, or any other such like configuration. Alternatively, some operations or methods may be performed by circuitry that is specific to a given function.

In one or more aspects, the functions described may be implemented in hardware, software, firmware, or any combination thereof. If implemented in software, the functions may be stored as one or more instructions (or code) on a non-transitory computer-readable storage medium or a non-transitory processor-readable storage medium. The operations of a method or algorithm disclosed may be embodied in a processor-executable software module or as processor-executable instructions, both of which may reside on a non-transitory computer-readable or processor-readable storage medium. Non-transitory computer-readable or processor-readable storage media may be any storage media that may be accessed by a computer or a processor (e.g., RAM, flash, etc.). By way of example but not limitation, such non-transitory computer-readable or processor-readable storage media may include RAM, ROM, EEPROM, NAND FLASH, NOR FLASH, M-RAM, P-RAM, R-RAM, CD-ROM, DVD, magnetic disk storage, magnetic storage smart objects, or any other medium that may be used to store program code in the form of instructions or data structures and that may be accessed by a computer. A disk may refer to magnetic or non-magnetic storage operable to store instructions or code. Disc refers to any optical disc operable to store instructions or code. Combinations of any of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed aspects is provided to enable any person skilled in the art to make, implement, or use the claims. Various modifications to these aspects will be readily apparent to those skilled in the art, and the generic principles defined may be applied to other aspects without departing from the scope of the claims. Thus, the present disclosure is not intended to be limited to the aspects illustrated but is to be accorded the widest scope consistent with the claims disclosed.

1. A method for generating a dynamic control point for generating an optimized curve, the method comprising:
determining, at at least one processor, an initial curve;
setting, at the at least one processor, a control point sampling interval;
setting, at the at least one processor, a condition;
determining, at the at least one processor, a plurality of static control points;
sampling, at the at least one processor and based on the control point sampling interval, the plurality of static control points;
selecting, at the at least one processor, a sampled static control point from the plurality of static control points, the selecting being based on the sampled static control point satisfying the condition;
storing, at the at least one processor, the sampled static control point in a plurality of filtered control points;
sampling, at the at least one processor, the plurality of filtered control points;
selecting, at the at least one processor, a sampled filtered control point, the selecting being based on the control point sampling interval; and
generating, at the at least one processor and based on the sampled filtered control point, the dynamic control point.

2. The method of claim 1, further comprising generating, at the at least one processor, the optimized curve based on the dynamic control point.

3. The method of claim 2, in which the optimized curve is an alignment, a profile, or a combination thereof.

4. The method of claim 1, in which the condition is based on an elevation selected from a group consisting of: at-grade elevation, above-grade elevation, and below-grade elevation.

5. The method of claim 1, in which the condition is based on an elevation relative to a boundary of a geological layer.

6. The method of claim 1, the method further comprising:
performing, at the at least one processor, a benchmarking test;
generating, at the at least one processor, a plurality of metrics; and
presenting, at the at least one processor, the plurality of metrics on a display.

7. An apparatus to generate a dynamic control point for generating an optimized curve, the apparatus comprising:
at least one memory; and
at least one processor coupled to the at least one memory, the at least one processor being configured:
to determine an initial curve;
to set a control point sampling interval and a condition;
to determine a plurality of static control points;
to sample, based on the control point sampling interval, the plurality of static control points;
to select a sampled static control point from the plurality of static control points based on the sampled static control point satisfying the condition;
to store the sampled static control point in a plurality of filtered control points;
to sample the plurality of filtered control points;
to select a sampled filtered control point based on the control point sampling interval; and
to generate the dynamic control point based on the sampled filtered control point.

8. The apparatus of claim 7, in which the at least one processor is further configured to generate the optimized curve based on the dynamic control point.

9. The apparatus of claim 8, in which the optimized curve is an alignment, a profile, or a combination thereof.

10. The apparatus of claim 7, in which the at least one processor is further configured to set the condition based on an elevation selected from a group consisting of: at-grade elevation, above-grade elevation, and below-grade elevation.

11. The apparatus of claim 7, in which the at least one processor is further configured to set the condition based on an elevation relative to a boundary of a geological layer.

12. The apparatus of claim 7, in which the at least one processor is further configured:
to perform a benchmarking test;
to generate a plurality of metrics; and
to present the plurality of metrics on a display.

13. A non-transitory computer readable medium having encoded thereon program code for generating a dynamic control point for generating an optimized curve, the program code being executed by a processor and comprising:
program code to set a control point sampling interval and a condition;
program code to determine a plurality of static control points;
program code to sample, based on the control point sampling interval, the plurality of static control points;
program code to select a sampled static control point from the plurality of static control points based on the sampled static control point satisfying the condition;
program code to store the sampled static control point in a plurality of filtered control points;
program code to sample the plurality of filtered control points;
program code to select a sampled filtered control point based on the control point sampling interval; and
program code to generate the dynamic control point based on the sampled filtered control point.

14. The non-transitory computer readable medium of claim 13, further comprising program code to generate the optimized curve based on the dynamic control point.

15. The non-transitory computer readable medium of claim 14, in which the optimized curve is an alignment, a profile, or a combination thereof.

16. The non-transitory computer readable medium of claim 13, further comprising program code to set the condition based on an elevation selected from a group consisting of: at-grade elevation, above-grade elevation, and below-grade elevation.

17. The non-transitory computer readable medium of claim 13, further comprising program code to set the condition based on an elevation relative to a boundary of a geological layer.

18. The non-transitory computer readable medium of claim 13, further comprising:
program code to perform a benchmarking test;
program code to generate a plurality of metrics; and
program code to present the plurality of metrics on a display.
